(19) United States
(12) Patent Application Publication
(10) Pub. No.: US 2008/0128880 A1
(43) Pub. Date: Jun. 5, 2008

(54) DIE STACKING USING INSULATED WIRE BONDS

(76) Inventors: Hem Takiar, Fremont, CA (US); Shrikar Bhagath, San Jose, CA (US)

Correspondence Address: VIERRA MAGEN/SANDISK CORPORATION, 575 MARKET STREET, SUITE 2500, SAN FRANCISCO, CA, 94105, US

(21) Appl. No.: 11/694,713

(22) Filed: Mar. 30, 2007

Related U.S. Application Data
(63) Continuation of application No. 11/566,097, filed on Dec. 1, 2006.

(51) Int. Cl. H01L 25/065

(52) U.S. Cl. 257/686; 257/E25.013

(57) ABSTRACT

A low profile semiconductor package is disclosed including at least first and second stacked semiconductor die mounted to a substrate. The first and second semiconductor die are separated by a low profile intermediate adhesive layer. After the intermediate layer is applied, the second semiconductor die may be stacked on top of the intermediate layer. The first semiconductor layer may be wire-bonded to the substrate using bond wires sheathed within an electrical insulator. As the bond wires are surrounded by an electrical insulator, the intermediate layer need not space the wire bond loops from the second semiconductor die as in the prior art, and the apex of bond wires may come into contact with the dielectric layer. The intermediate layer may thus be made thinner in comparison to conventional stacked semiconductor die configurations.

### CROSS-REFERENCE TO RELATED APPLICATION

This application is a continuation of U.S. patent application Ser. No. 11/566,097 filed on Dec. 1, 2006, entitled “Method of Fabricating A Film-On-Wire Bond Semiconductor Device,” which application is incorporated by reference in its entirety herein.

### CROSS-REFERENCE TO RELATED APPLICATIONS

The following application is cross-referenced and incorporated by reference herein in its entirety:

U.S. patent application Ser. No. ______ [Attorney Docket No. SAND-01226US0], entitled “METHOD OF DIE STACKING USING INSULATED WIRE BONDS,” by Hem Takiar et al., filed concurrently herewith.

### BACKGROUND OF THE INVENTION

1. Field of the Invention

Embodiments of the present invention relate to a low profile semiconductor device and method of fabricating same.

2. Description of the Related Art

The strong growth in demand for portable consumer electronics is driving the need for high-capacity storage devices. Non-volatile semiconductor memory devices, such as flash memory storage cards, are becoming widely used to meet the ever-growing demands on digital information storage and exchange. Their portability, versatility and rugged design, along with their high reliability and large capacity, have made such memory devices ideal for use in a wide variety of electronic devices, including for example digital cameras, digital music players, video game consoles, PDAs and cellular telephones.

While a wide variety of packaging configurations are known, flash memory storage cards may in general be fabricated as system-in-a-package (SiP) or multichip modules (MCM), where a plurality of die are mounted on a substrate. The substrate may in general include a rigid, dielectric base having a conductive layer etched on one or both sides. Electrical connections are formed between the die and the conductive layer(s), and the conductive layer(s) provide an electric lead structure for connection of the die to a host device. Once electrical connections between the die and substrate are made, the assembly is then typically encased in a molding compound to provide a protective package.

A cross-section of a conventional semiconductor package 18 (without molding compound) is shown in FIG. 1. Typical packages include a plurality of semiconductor die. The die may be affixed to the substrate via die attach adhesive layer 24. Generally, the substrate 22 is formed of a rigid core 28, of for example polyimide laminate. Thin film copper layer(s) 30 may be formed on the core in a desired electrical lead pattern using known photolithography and etching processes. Exposed surfaces of the conductance pattern may be plated for example with one or more layers of gold in a plating process to form contact pads for electrical connection of the semiconductor die to the substrate and electrical connection of the substrate to a host device. The substrate may be coated with a solder mask 36, leaving the contact pads exposed, to insulate and protect the electrical lead pattern formed on the substrate. Bond pads on the semiconductor die may be electrically connected to the plated contact pads on the substrate by wire bonds 34.

It is known to layer semiconductor die on top of each other either with an offset or in a stacked configuration. In an offset configuration, a die is stacked on top of another die so that the bond pads of the lower die are left exposed. An offset configuration provides an advantage of convenient access of the bond pads on each of the semiconductor die. However, the offset requires a greater footprint on the substrate, where space is at a premium.

In stacked configurations, such as that shown in prior art FIG. 1, two or more semiconductor die are stacked directly on top of each other, thereby taking up less footprint on the substrate as compared to an offset configuration. However, in a stacked configuration, space must be provided between adjacent semiconductor die for the bond wires 34. In addition to the height of the bond wires 34 themselves, additional space must be left above the bond wires, as contact of the bond wires 34 of one die with the next die above may result in an electrical short. As shown in FIG. 1 and the enlarged view of FIG. 2, it is therefore known to bury the wire bond loops between two adjacent semiconductor die within the adhesive layer 26 between the respective die. Such configurations are shown for example in U.S. Pat. No. 6,388,313 to Lee et al., entitled, “Multi-Chip Module,” and U.S. Pat. No. 7,037,756 to Jiang et al., entitled, “Stacked Microelectronic Devices and Methods of Fabricating Same.” These references disclose semiconductor die packages as in prior art FIGS. 1 and 2 of the present invention where wire bond loops 34 are buried within an adhesive layer 26 having a sufficient thickness to prevent shorting of the wire bond loops against the lower surface of the upper die 20.

There is an ever-present drive to increase storage capacity within memory modules. One method of increasing storage capacity is to increase the number of memory die used within the package. In portable memory packages, the number of die which may be used is limited by the thickness of the package. There is accordingly a keen interest in decreasing the thickness of the contents of a package while increasing memory density. The package 18 shown in FIGS. 1 and 2 requires the adhesive layer 26 separating the semiconductor die to be thicker than is otherwise necessary so as to ensure that the wire bond loops remain buried and do not contact the underside of the next adjacent semiconductor die during fabrication. This additional thickness of the adhesive layer becomes even more of a problem in packages having more than two stacked die and multiple layers of adhesive having embedded wire bond loops.

### SUMMARY OF THE INVENTION

An embodiment of the present invention relates to a low profile semiconductor package including at least first and second stacked semiconductor die mounted to a substrate. The first and second semiconductor die are separated by a low profile intermediate layer in which the wire bond loops between the first semiconductor die and substrate are embedded. In accordance with the present invention, the wire bonds may comprise an electrically conductive wire sheathed within an electrical insulator. The intermediate layer may be an electrically insulative epoxy applied as a viscous liquid onto the first semiconductor die. The intermediate layer may be applied over at least substantially the entire surface of the first semiconductor die, or only in discrete quantities over the bond pads of the first semiconductor die.

After the intermediate layer is applied, the second semiconductor die may be stacked on top of the intermediate layer. As the wire bonds are sheathed within an electrical insulator, the intermediate layer need not space the wire bond loops from the second semiconductor die as in the prior art, and the apex of bond wires may come into contact with the second semiconductor layer. The spacing between the first and second stacked semiconductor die may thus be made thinner in comparison to conventional stacked semiconductor die configurations. The second semiconductor die may further be affixed under a compressive load so as to reduce a thickness of the intermediate layer, as well as partially flattening the height of the bond wires above the surface of the first semiconductor die.

Once all semiconductor die are affixed and wire bonded to the substrate, the semiconductor package may be cured, including for example by heating and/or by ultraviolet radiation. In an alternative embodiment, the intermediate layer may be cured before the second semiconductor die is affixed thereto.

### DESCRIPTION OF THE DRAWINGS

FIG. 1 is a cross sectional side view of a portion of a conventional semiconductor package including stacked semiconductor die mounted on a substrate.

FIG. 2 is an enlarged cross sectional side view of a portion of the semiconductor package shown in FIG. 1.

FIG. 3A is a flowchart of the fabrication of the semiconductor package according to an embodiment of the present invention.

FIG. 3B is a flowchart of the fabrication of the semiconductor package according to an alternative embodiment of the present invention.

FIG. 4 is a cross sectional side view of a portion of the semiconductor package of the present invention during fabrication.

FIG. 5 is a top view of the portion of the semiconductor package of the present invention shown in FIG. 4.

FIG. 6A is a cross sectional side view of a portion of the semiconductor package of the present invention during fabrication.

FIG. 6B is a cross sectional side view of a portion of the semiconductor package of an alternative embodiment of the present invention during fabrication.

FIG. 7 is a cross sectional side view of a portion of the semiconductor package of the present invention during fabrication.

FIG. 8 is a cross sectional side view of a portion of the semiconductor package of an alternative embodiment of the present invention during fabrication.

FIG. 9 is a cross sectional side view of a portion of the semiconductor package of a further alternative embodiment of the present invention during fabrication.

FIG. 10 is a top view of a portion of the semiconductor package of the alternative embodiment shown in FIG. 9.

FIG. 11 is a cross sectional side view of a portion of the semiconductor package shown in FIG. 9 during fabrication.

FIG. 12 is a cross sectional side view of a portion of the semiconductor package shown in FIG. 9 during fabrication.

FIG. 13 is a cross sectional side view of a semiconductor package according to embodiments of the present invention.

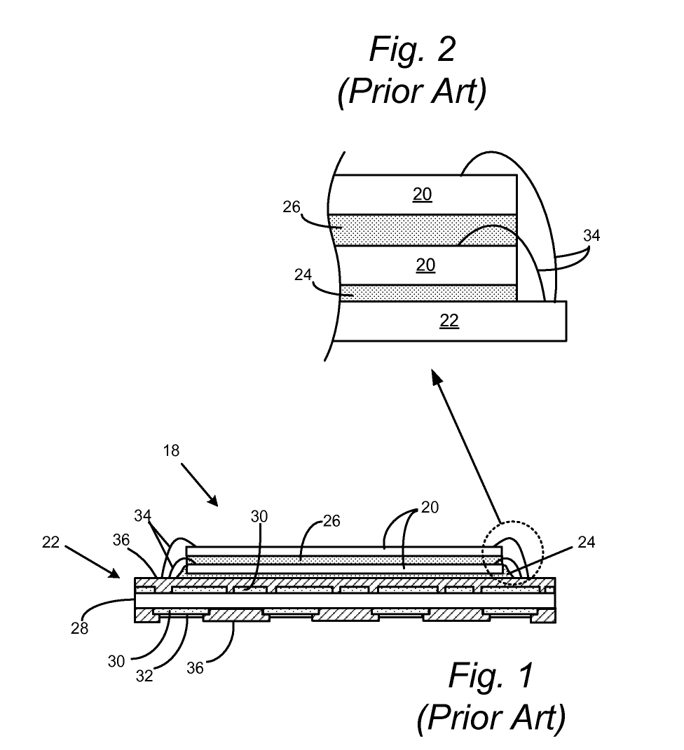

### DETAILED DESCRIPTION

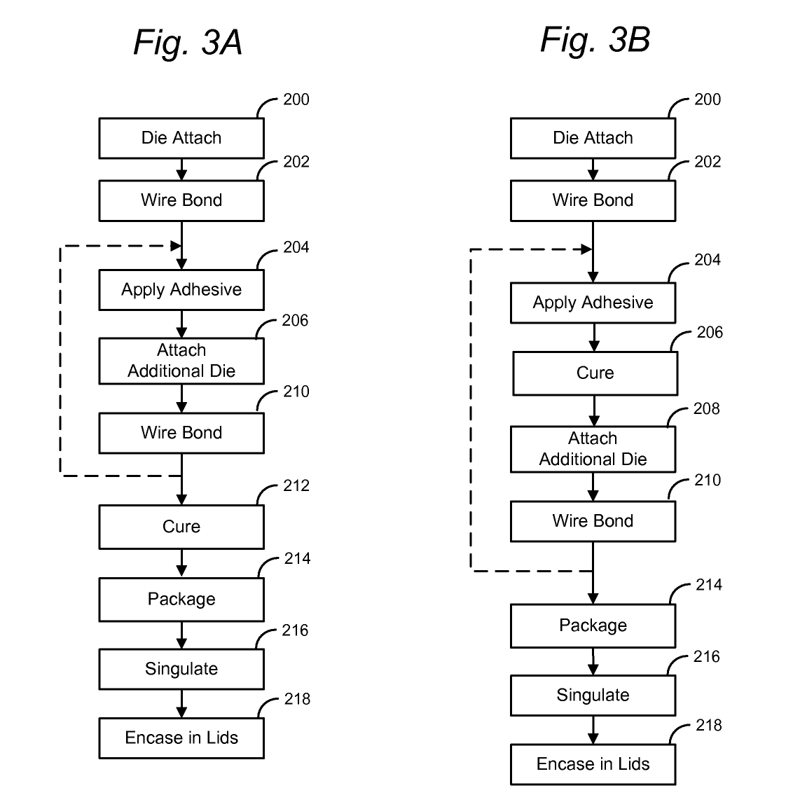

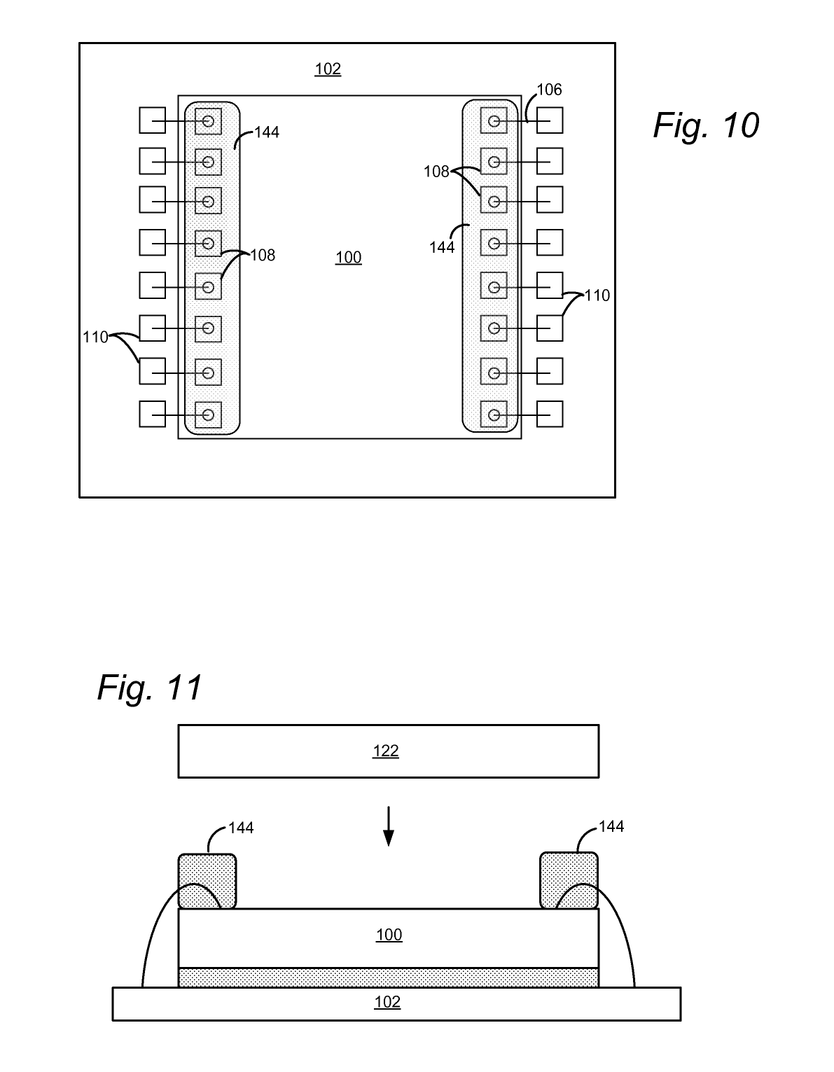

Embodiments will now be described with reference to FIGS. 3A through 13, which relate to a low profile semiconductor package. It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

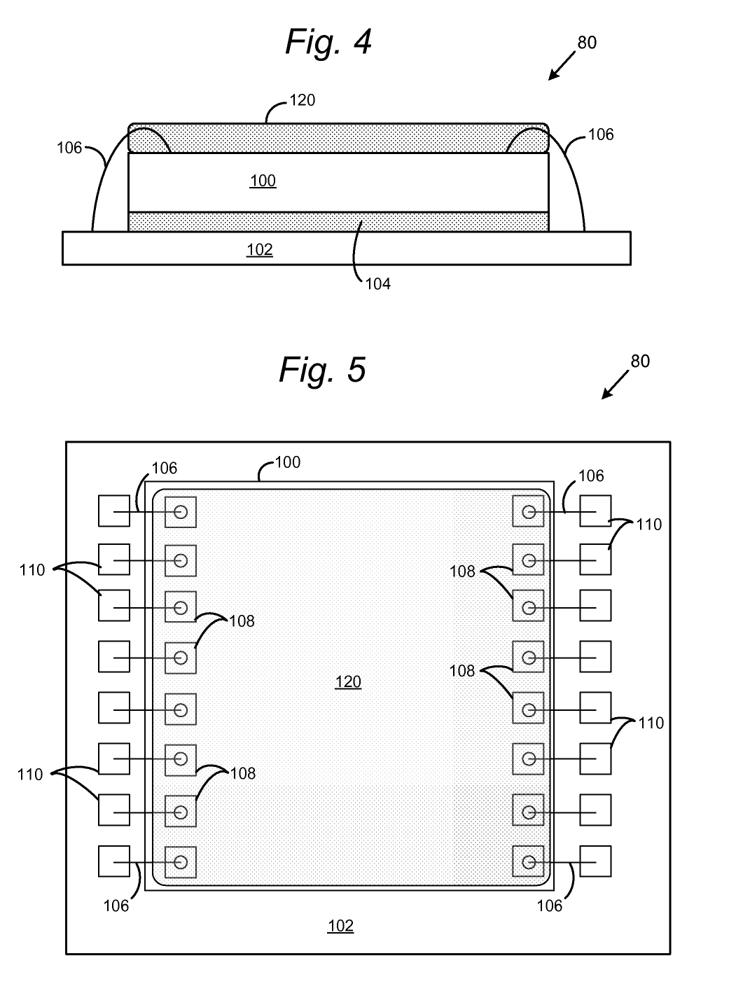

The present invention will now be described with reference to the flowchart of FIG. 3A and the side and top views shown in FIGS. 4-13. Embodiments of the present invention relate to a semiconductor package 80, a portion of which includes a first semiconductor die 100 mounted in step 200 to a substrate 102 as shown in FIGS. 4 and 5. The die 100 may be mounted to substrate 102 via a die attach adhesive layer 104 in a known adhesive or eutectic die bond process. The die attach adhesive layer 104 may for example be an epoxy of known construction available for example from Nitto Denko Corp. of Japan, Abelstik Co., California or Henkel Corporation, California. As explained hereinafter, the adhesive layer 104 may be applied as a viscous liquid, which remains in that state until cured in a reflow process.

Although not critical to the present invention, substrate 102 may be a variety of different chip carrier mediums, including a PCB, a leadframe or a tape automated bonded (TAB) tape. Where substrate 102 is a PCB, the substrate may be formed of a core having top and/or bottom conductive layers formed thereon. The core may be various dielectric materials such as for example, polyimide laminates, epoxy resins including FR4 and FR5, bismaleimide triazine (BT), and the like.

The conductive layers may be formed of copper or copper alloys, plated copper or plated copper alloys, Alloy 42 (42FE/58NI), copper plated steel or other metals or materials known for use on substrates. The conductive layers may be etched into a conductance pattern as is known for communicating signals between the semiconductor die and an external device. A dummy pattern may also be provided in the conductive layers as is known to reduce mechanical stresses on the substrate otherwise resulting from uneven thermal expansion within the substrate. Substrate 102 may additionally include exposed metal portions forming contact pads 110 (FIG. 5) and/or contact fingers (as in an example where the package 80 is a land grid array (LGA) package). The contact pads and/or fingers may be plated with one or more gold layers, for example in an electroplating process as is known in the art.

After semiconductor die 100 is affixed to substrate 102 in step 200, bond wires 106 may be attached between bond pads 108 (FIG. 5) on die 100 and bond pads 110 on substrate 102 in a step 202. Bond wires 106 may be affixed in a known wire bonding process. In accordance with the present invention, the bond wires may include an electrically conductive wire sheathed within an electrical insulator as explained in greater detail hereinafter. In embodiments, the wire bond process may be a low-profile wire bond process, such as for example a reverse bonding process. In the embodiments shown in FIGS. 4 and 5, wire bonds are provided along two opposed sides of die 100. In alternative embodiments of the present invention, wire bonds 106 may be provided along a single side, or three or four sides of die 100.

In step 204, an intermediate layer 120 may be applied onto the exposed surface of die 100. The intermediate layer 120 may for example be an electrically insulative adhesive epoxy of known composition available for example from Nitto Denko Corp. of Japan, Abelstik Co., California or Henkel Corporation, California. The intermediate layer 120 may be applied as a viscous liquid, which remains in that state until cured in a reflow process explained hereinafter. In embodiments, the intermediate layer 120 is applied as a liquid, but has a sufficiently high viscosity to mechanically support a second semiconductor die placed on layer 120 as explained hereinafter. In embodiments, the viscosity may be for example about 1-2×106 centipoise, but it is understood that the viscosity may be higher or lower than that in alternative embodiments. The intermediate layer 120 may be the same as or different from the material used as the adhesive layer 104. In an alternative embodiment, spacer balls may be provided within the intermediate layer 120. The spacer balls may be polymeric spheres that act as spacers between the die 100 and a second die mounted thereon as explained hereinafter. Such spacer balls are known in the art, and are disclosed for example in U.S. Pat. No. 6,650,019, entitled, “Method of Making a Semiconductor Package Including Stacked Semiconductor Die,” which patent is incorporated herein by reference in its entirety.

As seen in FIGS. 4 and 5, in an embodiment, the intermediate layer 120 may be applied over at least substantially the entire surface of die 100 (some of the edges may or may not be devoid of adhesive material). The adhesive material of layer 120 is applied such that the wire bond loops 106 are partially buried within the layer 120. Namely, the portion of bond wires 106 adjacent bond pads 108 as well as an apex of the bond loops are buried within intermediate layer 120. As intermediate layer 120 is applied only over the surface of die 100, portions of the wire 106 extending outside of the footprint of die 100 are not embedded within intermediate layer 120.

In addition to adhering the stacked semiconductor die together within the package 80, the intermediate layer 120 provides some spacing between the two stacked semiconductor die for location of the wire bond loops 106. However, no additional space in the intermediate layer is required to separate the wire bond loops 106 from a next adjacent semiconductor die. In particular, in the prior art, the adhesive layer in which the bond wires were embedded needed to be thick enough to ensure the bond wires would be prevented from shorting against the bottom surface of the next adjacent die. However, as explained in greater detail hereinafter, the bond wires may be sheathed in an electrical insulator. Accordingly, intermediate layer 120 need not space wire bond loops 106 from the next adjacent die as in the prior art, and the spacing between the stacked die may be made thinner in comparison to conventional stacked semiconductor die configurations. For example, the intermediate layer 120 may be between 25-50 microns (μm), as compared to about 75 μm in the prior art. It is understood that the thickness of the intermediate layer 120 may be less than 25 μm and greater than 50 μm in alternative embodiments of the present invention.

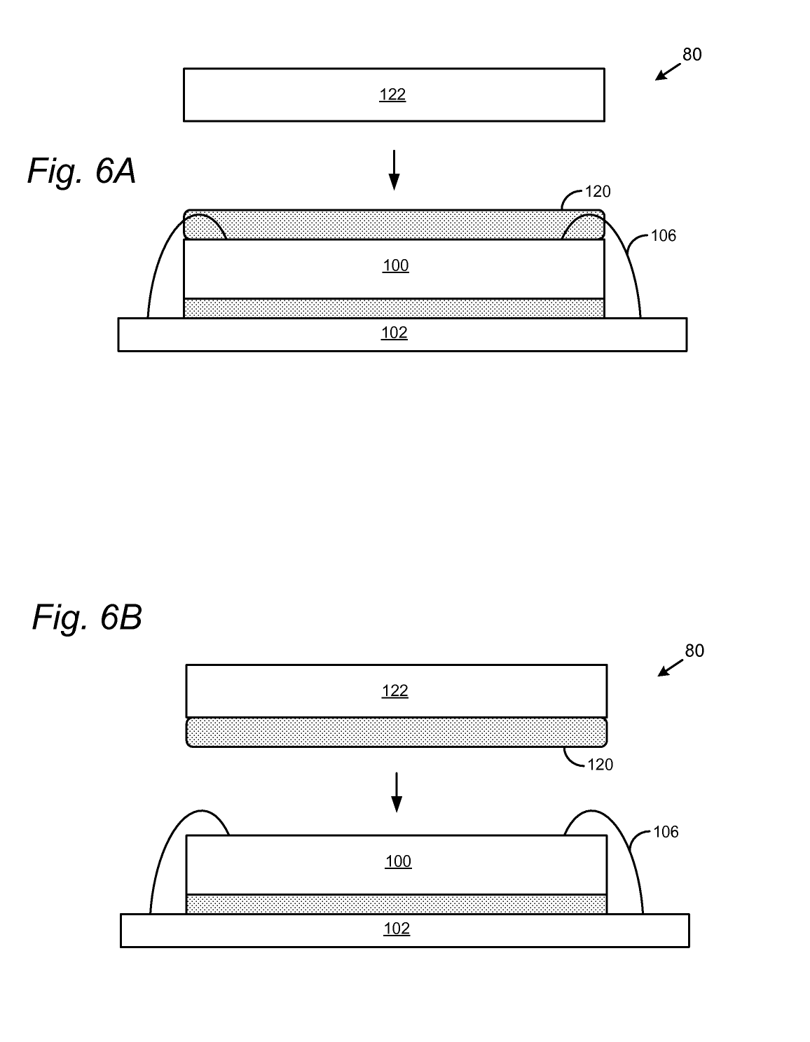

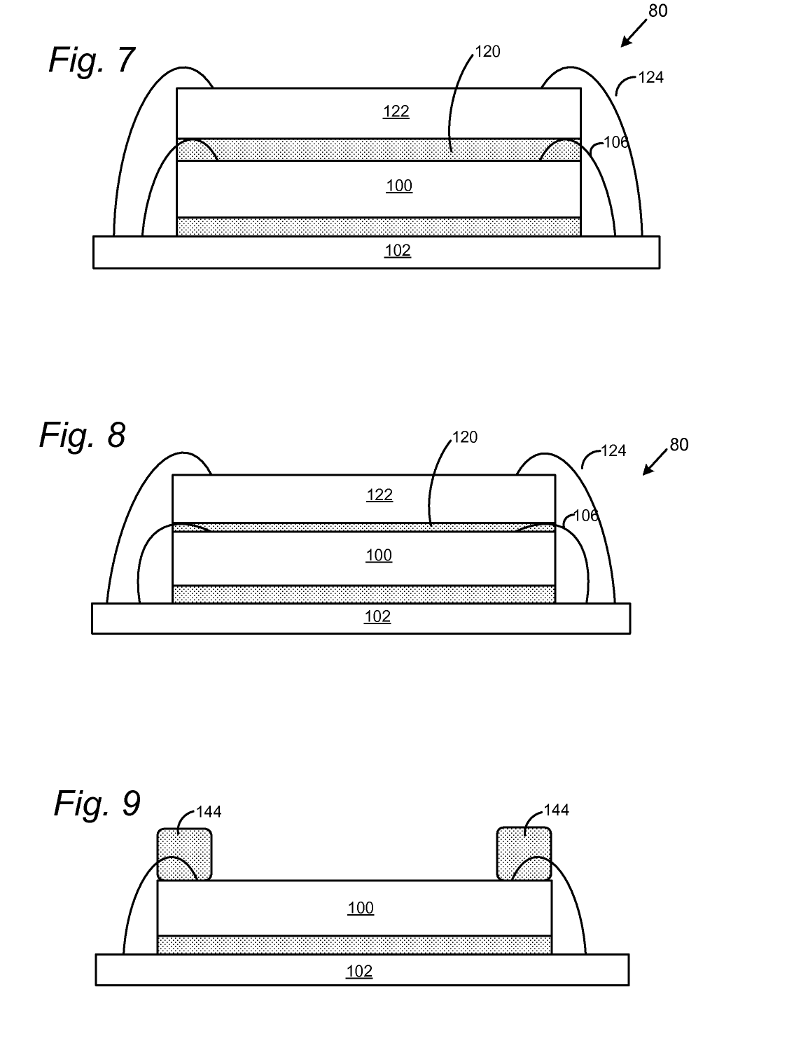

As indicated above, in step 206, a second semiconductor die 122 may be stacked on top of the intermediate layer 120 as shown in FIGS. 6A, 6B and 7. The die 122 may be lowered onto the intermediate layer 120 on die 100 as shown in FIG. 6A. In an alternative embodiment shown in FIG. 6B, the adhesive layer 120 may be formed on a bottom surface of the second die 122, and lowered onto the die 100 and wire bonds 106. In the embodiment of FIG. 6B, the adhesive layer 120 may extend to the edges of semiconductor die 122 so that, once die 100 and 122 are brought together, the wire bonds get embedded within layer 120. Alternatively, the adhesive layer 120 may be provided at a center portion of die 122 so that, once die 100 and 122 are brought together, the wire bonds are not embedded within layer 120. Once die 122 is affixed onto die 100 as shown in FIG. 7, die 122 may be wire bonded to substrate 102 in a step 210 using bond wires 124 in a known wire bond process.

Embodiments of the present invention may include only the pair of semiconductor die 100 and 122. However, in further embodiments, more than two semiconductor die may be stacked atop each other. In such embodiments, as indicated by the dashed arrow in FIG. 3A, steps 204 of applying an adhesive on the upper surface of the upper die, step 206 of attaching an additional die and step 210 of wire bonding the additional die may be repeated for each additional semiconductor die stacked on top of die 122.

As indicated above, intermediate layer 120 is applied with a viscosity sufficient to support semiconductor die 122 without excessively flattening wire bond loops 106. However, when semiconductor die 122 is attached to intermediate layer 120, pressure may be exerted on the intermediate layer so as to reduce the thickness of intermediate layer 120. In so doing, the apex of bond wires 106 may come into contact with second semiconductor die 122 as shown in FIG. 7. However, as the electrical isolator around the bond wires electrically isolates each of the wire bonds 106 from each other and semiconductor die 122, no electrical short occurs.

In a further embodiment shown in FIG. 8, semiconductor die 122 may be affixed to package 140 under a compressive load so as to reduce a thickness of intermediate layer 120 as described above, as well as partially flattening the height of bond wires 106 above the surface of semiconductor 100. The thickness of layer 120 and the height of bonded wires 106 may be reduced an amount determined not to jeopardize the structural integrity of the wire bond connection to semiconductor die 100. As indicated above, in embodiments, this thickness may be between 25 and 50 μm, though it may be more or less than that in alternative embodiments.

Once all semiconductor die are affixed and wire bonded to substrate 102, the semiconductor package 80 may be cured in a reflow process of step 212 to harden each of the adhesive layers, including intermediate layer 120 and die attach layer 104. Curing may be accomplished by a variety of known methods, depending on the adhesive material used, including for example by heating and/or by ultraviolet radiation.

In the embodiment described above with respect to the flowchart of FIG. 3A, the package 80 is not cured until after all semiconductor die have been stacked and wire bonding has been completed. In an alternative embodiment of the present invention described with respect to the flowchart in FIG. 3B, the intermediate layer 120 and die bond layer 104 may be cured in step 206 prior to affixing the semiconductor die 122 (the layers 104 and 120 in this embodiment may either be cured at the same time or at different times in step 206). In such an embodiment, the second semiconductor die may include a curable adhesive so that semiconductor die 122 may be attached to cured intermediate layer 120 and thereafter firmly affixed, as in a subsequent curing process. It is further contemplated that die bond layer 104 and/or the intermediate layer 120 may be partially cured to a b-stage in step 206. The layers 104 and/or 106 may thereafter be fully cured after affixation of semiconductor die 122.

In embodiments described above, the intermediate layer 120 may be an adhesive material. However, the intermediate layer 120 need not be an adhesive. In such an embodiment, the layer 120 may be applied as a liquid around bond wires 106 and act only as a spacer layer spacing the die 100 and 122 from each other and electrically isolating the bond wires 106 from each other. The die 100 and 122 in such an embodiment would be affixed to each other by an adhesive layer.

An alternative embodiment of the present invention is shown in FIGS. 9-12. In such an embodiment, instead of intermediate layer 120 being applied over substantially the entire surface of semiconductor die 100, the intermediate layer is applied as discrete quantities of adhesive material 144 only over and adjacent the contact pads 108 on semiconductor die 100. In particular, the adhesive material 144 may be applied to a first area on semiconductor die 100 including bond pads 108, and not applied to a second area on die 100 not including the bond pads. Such an embodiment may be used where there are one, two, three or four sides of contact pads 108 on semiconductor die 100.

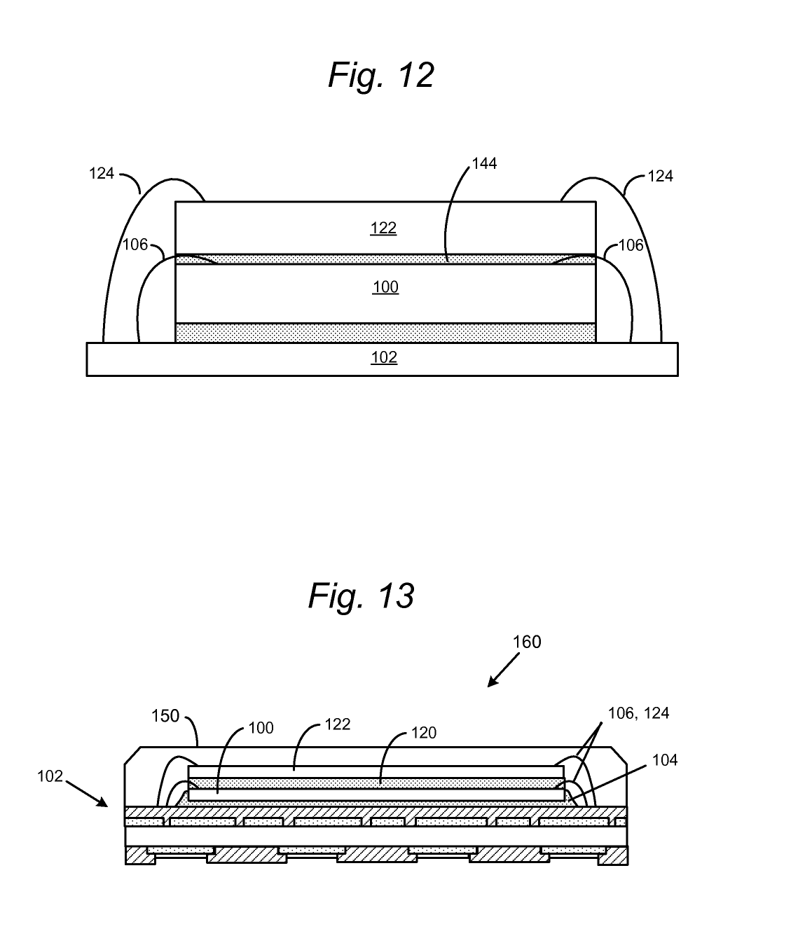

In this alternative embodiment, as indicated in FIGS. 11 and 12, when second semiconductor die 122 is affixed to the package, a compressive force may slightly flatten the adhesive 144. As indicated above, in addition to flattening adhesive 144, the compressive force may also reduce the height of the apex of the wire bond loop 106 above the surface of semiconductor die 100 Thereafter, during the curing process, the adhesive areas may further flatten and spread the adhesive 144 out across the surface of die 100. It is understood that liquid adhesive 144 may not entirely cover the surface of die 100 upon the attachment of die 122 and/or the subsequent curing process.

Once die 122 is affixed to the die 100 in the embodiment of FIGS. 9-12, the second semiconductor die 122 may be wire bonded to substrate 102 with wire bonds 124 in a known wire bond process. The package may then be cured as described above.

In the above-described embodiments, the bond wires from die 100 and 122 may be gold, though it may alternatively be copper, aluminum or other metals. In accordance with the present invention, the bond wires from die 100 and/or 122 may be pre-insulated (i.e., prior to be immersed in intermediate layer 120) with polymeric insulation that makes the surface of the wire electrically non-conductive. Such pre-insulated bond wire is known for preventing shorting between adjacent bond wires. Two examples of a pre-insulated bond wire which is suitable for use in the present invention are disclosed in U.S. Pat. No. 5,396,104, entitled, “Resin Coated Bonding Wire, Method of Manufacturing the Same, and Semiconductor Device,” and U.S. Published Patent Application No. 2004/0124545, entitled, “High Density Integrated Circuits and the Method of Packaging the Same,” both of which are incorporated by reference herein in their entirety.

As set forth for example in those references, the insulation film applied around the bond wires may be composed of an electric insulation polymer material, such as for example aromatic polyester, polyimide, or other insulators. The insulation film can be formed in such a manner that the metal core wire is caused to pass through a solution prepared by dissolving the polymer material in solvent and then the solvent is volatilized, the metal core wire is caused to pass through the melted polymer material prepared by heating it and then it is cooled. Alternatively, the polymer material is sprayed on the surface of the metal core material. Further still, a monomer may be deposited on the surface of the metal core material and then it is polymerized by being heated or subjected to photochemical polymerization.

The insulation may decompose under high temperature so that, when the bond wire is bonded to bonding pads, only the insulation film located at a bonding position is decomposed or melted from the surface of the metal core wire. The parent application discloses a dielectric layer 130 formed on the second semiconductor die. An embodiment utilizing a pre-insulated bond wire may operate with or without dielectric layer 130. An embodiment utilizing a pre-insulated bond wire may operate with or without intermediate layer 120. In such an embodiment operating without intermediate layer 120, there may be an adhesive for affixing the die together.

As shown in FIG. 13, after forming the stacked die configuration according to any of the above described embodiments, the configuration may be encased within the molding compound 150 in step 214, and singulated in step 216, to form a finished semiconductor die package 160. Molding compound 150 may be a known epoxy such as for example available from Sumitomo Corp. and Nitto Denko Corp., both having headquarters in Japan. Thereafter, the finished package 160 may optionally be enclosed within a lid in step 218.

In embodiments, the semiconductor die described above may include one or more flash memory chips, and possibly a controller such as an ASIC, so that the package 160 may be used as a flash memory device. It is understood that the package 160 may include semiconductor die configured to perform other functions in further embodiments of the present invention.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

We claim:

1. A semiconductor device, comprising:
a first semiconductor die including first and second opposed surfaces, the first surface including a plurality of bond pads;
a plurality of bond wires, each bond wire of the plurality of bond wires sheathed in an electrical insulator and having an end affixed to a bond pad of the first semiconductor die;
an intermediate layer applied to the first surface of the first semiconductor die; and
a second semiconductor die, the electrical insulator around the bond wires provided to prevent electrical coupling between the plurality of bond wires and the second semiconductor die.

2. A semiconductor device as recited in claim 1, wherein the intermediate layer is a rigid spacer layer.

3. A semiconductor device as recited in claim 1, wherein the intermediate layer is a liquid layer.

4. A semiconductor device as recited in claim 3, wherein the plurality of bond wires are embedded within the intermediate layer.

5. A semiconductor device as recited in claim 3, wherein the plurality of bond wires are spaced from the intermediate layer.

6. A semiconductor device as recited in claim 1, wherein the electrical insulator within which the bond wires are sheathed is formed of one of a polyimide and a polyester.

7. A semiconductor device as recited in claim 1, wherein the intermediate layer covers a first area on the first surface including the bond wires and not covering a second area of the first surface not including the bond wires.

8. A semiconductor device as recited in claim 1, wherein the intermediate layer is an adhesive layer for affixing the first and second semiconductor die together.

9. A semiconductor device as recited in claim 1, wherein the intermediate layer is an epoxy layer for affixing the first and second semiconductor die together.

10. A semiconductor device as recited in claim 1, wherein the bond wires are affixed to the first semiconductor die in a bond loop shape, the intermediate layer having a height above the first surface of the first semiconductor die approximately equal to a height of an uppermost portion of the bond loops above the first surface of the first semiconductor die.

11. A semiconductor device as recited in claim 1, wherein the plurality of bond wires are provided adjacent a single edge of the first surface of the first semiconductor die.

12. A semiconductor device as recited in claim 1, wherein the plurality of bond wires are provided along two or more edges of the first surface of the first semiconductor die.

13. A semiconductor device as recited in claim 1, wherein the semiconductor device is a flash memory device.

14. A semiconductor device as recited in claim 1, wherein the intermediate layer includes a plurality of spacer balls.

15. A semiconductor device, comprising:
a first semiconductor die including first and second opposed surfaces, the first surface including a plurality of bond pads;
a plurality of bond wires, each bond wire of the plurality of bond wires having an end affixed to a bond pad of the first semiconductor die and forming a bond loop;
an electrical insulator within which the plurality of bond wires are sheathed;
an adhesive layer applied to the first surface of the first semiconductor die, at least a portion of the bond loop for each of the plurality of bond wires embedded within the adhesive layer;
a second semiconductor die affixed to the adhesive layer; and
an electrical insulating layer interposed between the second semiconductor die and the adhesive layer, the electrical insulator within which the plurality of bond wires are sheathed electrically insulating the second semiconductor die from the bond wires in the adhesive layer.

16. A semiconductor device as recited in claim 15, wherein the intermediate layer is a rigid spacer layer.

17. A semiconductor device as recited in claim 15, wherein the intermediate layer is a liquid layer.

18. A semiconductor device as recited in claim 17, wherein the plurality of bond wires are embedded within the intermediate layer.

19. A semiconductor device as recited in claim 17, wherein the plurality of bond wires are spaced from the intermediate layer.

20. A semiconductor device as recited in claim 15, wherein the electrical insulator within which the bond wires are sheathed is formed of one of a polyimide and a polyester.

21. A semiconductor device as recited in claim 15, wherein the adhesive layer is an epoxy.

22. A semiconductor device, comprising:
a first semiconductor die including first and second opposed surfaces, the first surface including a plurality of bond pads;
a plurality of bond wires, each bond wire of the plurality of bond wires having an end affixed to a bond pad of the first semiconductor die and forming a bond loop;
an electrical insulator within which the plurality of bond wires are sheathed;
an adhesive layer applied to the first surface of the first semiconductor die, at least a portion of the bond loop for each of the plurality of bond wires embedded within the adhesive layer;
a second semiconductor die affixed to the adhesive layer; and
an electrical insulating layer interposed between the second semiconductor die and the adhesive layer, the semiconductor package formed by the steps of:
(a) wire bonding a plurality of wires to a surface of the first semiconductor die to form a plurality of wire bond loops;
(b) forming the intermediate layer on the surface of the first semiconductor die receiving the plurality of wires in said step (a);
(c) affixing the second semiconductor die to the first semiconductor die;
(d) reducing a thickness of the intermediate layer under a compressive force exerted on the intermediate layer by the first and second semiconductor die; and
(e) preventing the plurality of wires from electrically coupling with the second semiconductor die by sheathing the plurality of bond wires in an electrical insulator.

23. A semiconductor package as recited in claim 22, wherein the electrical insulation around the bond wires is formed by passing the wires through a liquid solution of the electrical insulation.

24. A semiconductor package as recited in claim 22, wherein the electrical insulation around the bond wires is formed by spraying a liquid solution of the electrical insulation onto the wires.
